(19) United States
(12) Patent Application Publication
(10) Pub. No.: US 2023/0246078 A1
(43) Pub. Date: Aug. 3, 2023

(54) SEMICONDUCTOR SUBSTRATE AND METHOD FOR PRODUCING SAME

(71) Applicant: Sanan Japan Technology Corporation, Tokyo (JP)

(72) Inventors: Hiroshi Nakamura, Tokyo (JP); Shinichi Shioi, Tokyo (JP)

(73) Assignee: Sanan Japan Technology Corporation, Tokyo (JP)

(21) Appl. No.: 18/161,689

(22) Filed: Jan. 30, 2023

(30) Foreign Application Priority Data
Feb. 3, 2022 (JP) 2022015992

(51) Int. Cl. H01L 29/16; H01L 29/20; H01L 21/02

(52) U.S. Cl. CPC H01L 29/1608; H01L 29/2003; H01L 21/0217

(57) ABSTRACT

A semiconductor substrate includes a silicon carbide substrate, a first nitride film in contact with the upper surface of the silicon carbide substrate, a second nitride film in contact with an upper surface of the first nitride film, and a silicon oxide film in contact with the upper surface of the second nitride film. The first nitride layer is more nitrogen-rich than the second nitride layer.

### CROSS-REFERENCE TO RELATED APPLICATION(S)

This application claims priority to Japanese Application No. 2022-015992, filed Feb. 3, 2022, which are incorporated herein by reference, in their entirety, for any purpose.

### BACKGROUND OF THE INVENTION

### Field of the Invention

The present disclosure relates to a semiconductor substrate and a method of producing the semiconductor substrate.

### Description of the Related Art

Patent Document 1 (JP2019-149527) discloses a silicon carbide semiconductor device. The silicon carbide semiconductor device includes a semiconductor substrate made of silicon carbide and a gate insulating film provided on a surface of the semiconductor substrate, wherein a nitrogen-plane density at an interface between the semiconductor substrate and the gate insulating film is 6×10¹⁴/cm² to 1.2×10¹⁵/cm².

When an interface state density between a silicon carbide substrate and a layer thereon is high, a channel mobility decrease. There is a need for providing a semiconductor substrate having a high channel mobility by reducing the interface state density.

### SUMMARY OF THE INVENTION

Some examples described herein may address the above-described problems. Some examples described herein may has an object to provide a semiconductor substrate having a reduced interface state density and a high channel mobility, and a method of producing the same.

In some examples, a semiconductor substrate includes a silicon carbide substrate, a first nitride film in contact with an upper surface of the silicon carbide substrate, a second nitride film in contact with an upper surface of the first nitride film, and a silicon oxide film in contact with an upper surface of the second nitride film. The first nitride film is more nitrogen-enriched than the second nitride film.

### BRIEF DESCRIPTION OF THE DRAWING

FIG. 1 is a cross-sectional view of a semiconductor substrate.

FIG. 2 shows an example of an impurity profile.

FIG. 3 shows a method of producing a semiconductor substrate.

FIG. 4 shows a method of producing a semiconductor substrate according to another example.

### DETAILED DESCRIPTION

Embodiments will be described with reference to the accompanying drawings. In the drawings, the same or corresponding parts are denoted by the same reference numerals. Duplicate descriptions of such portions may be simplified or omitted.

Embodiment.

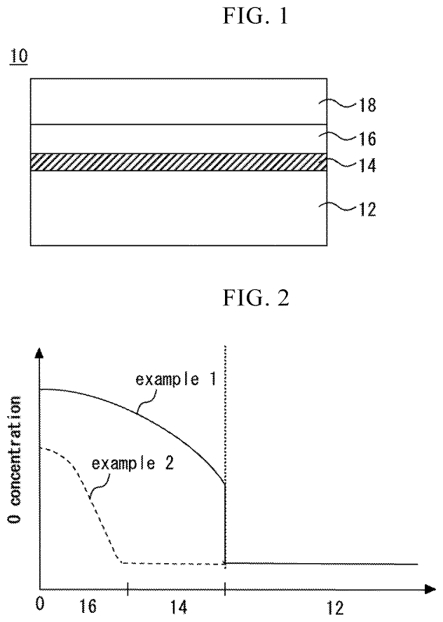

FIG. 1 is a cross-sectional view of a semiconductor substrate 10 according to an embodiment. The semiconductor substrate 10 includes a silicon carbide substrate 12.

According to one example, the silicon carbide substrate 12 is an n-type or p-type 4H—SiC. A first nitride film 14 is in contact with the upper surface of the silicon carbide substrate 12. A second nitride film 16 is in contact with the upper surface of the first nitride film 14.

More specifically, when the silicon carbide substrate 12 is the n-type 4H—SiC, the silicon carbide substrate 12 is formed of an n-type epitaxially grown layer having a low nitrogen concentration and high resistivity on a n+ type wafer having a high nitrogen concentration and low resistivity. All or part of a p-type region, a p+ type region, and a n+ type region may be formed by ion implantation or the like on a portion of the surface-side of the n-type epitaxial growth layer.

The epitaxial growth layer and an ion implantation region may be changed to n-type and p-type each, and the wafer may be p-type.

According to an example, the first nitride film 14 and the second nitride film 16 are silicon oxynitride. According to another example, the first nitride film 14 is silicon nitride, and the second nitride film 16 is silicon oxynitride.

In both examples, the first nitride film 14 may be more nitrogen-rich than the second nitride film 16.

In both examples, a compound forming the first nitride film 14 can be made more nitrogen-rich than the stoichiometric composition (stoichiometry) by mixing nitrogen atoms or the like between a crystal lattices of the first nitride film 14, or bonding nitrogen atoms or NH₂ to an uncombined hand (dangling bond) at the interface between the silicon carbide substrate 12 and the first nitride film 14.

That is, when the first nitride film 14 is silicon oxynitride (SiON), the number of N atoms are larger than that of Si atoms, and the number of N atoms are larger than that of 0 atoms. When the first nitride film 14 is made of silicon nitride (SiN), N atoms are larger than Si atoms. According to an embodiment, when the first nitride film 14 is made of silicon nitride, the compositional ratio (N/Si) of the nitrogen element to the silicon element can be set to 1.34 or more to 1.45 or less.

A silicon oxide film 18 is in contact with the upper surface of the second nitride film 16. According to an example, the thickness of the silicon oxide film 18 is larger than the sum of the thicknesses of the first nitride film 14 and the second nitride film 16.

According to another example, the thickness of the silicon oxide film 18 is 3 to 50 times the total thickness of the first nitride film 14 and the second nitride film 16.

In yet another example, the thickness of the silicon oxide film 18 may be 5 to 25 nm or 50 to 250 nm, and the sum of the thicknesses of the first nitride film 14 and the second nitride film 16 may be 1 to 10 nm.

The silicon oxide film 18 can be replaced with an arbitrary insulating film. The arbitrary insulating film such as a high-k film can be formed on the second nitride film 16 so as to obtain a desired SiO₂ equivalent thickness.

FIG. 2 shows an example of a concentration of an oxygen (O) element in each layer. In example 1 in FIG. 2, oxygen elements are present in the first nitride film 14 and the second nitride film 16. Any mixing or diffusion of significant oxygen atoms by oxide film formation is not occurred on the silicon carbide substrate 12 side.

In example 2 in FIG. 2, oxygen atoms are present in the second nitride film 16, but any mixing or diffusion of significant oxygen atoms by oxide film formation is not occurred on the first nitride film 14 and the silicon carbide substrate 12 side.

As described above, the suppression of the mixing or diffusion or oxidation of significant oxygen atoms to the silicon carbide substrate 12 maintains the bonding between the silicon on the top surface of the silicon carbide substrate 12 and the nitrogen or NH₂ at the interface between the silicon carbide substrate 12 and the upper layer. Consequently, the suppression reduces the interface state density.

According to another example, the density of oxygen atoms in the silicon carbide substrate 12 is lower than the density of nitrogen atoms. Some of the aforementioned bonds may be bonded to (—NO).

In the above description, the first nitride film 14 and the second nitride film 16 have been described as different films. However, according to an example, the compound of the first nitride film 14 and the compound of the second nitride film 16 may be common. In this case as well, the first nitride film 14 is a film that is more nitrogen-rich than the second nitride film.

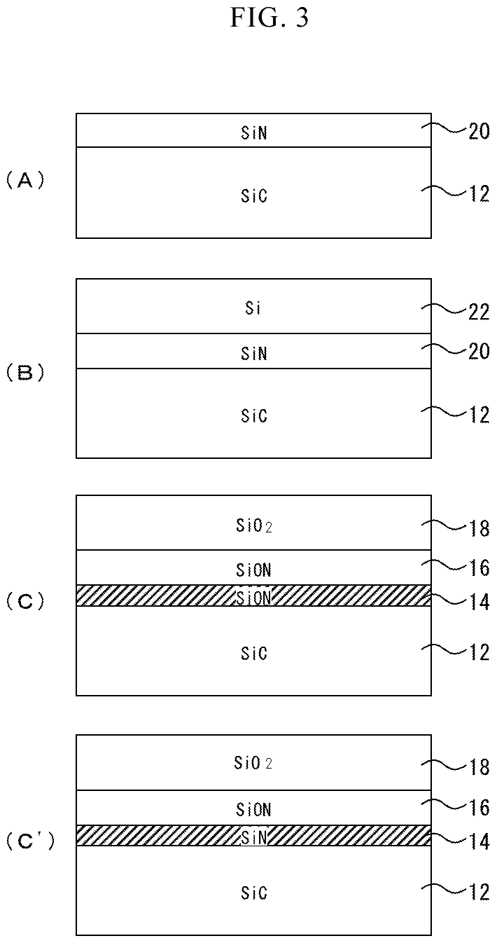

Referring to FIG. 3, a method of producing a semiconductor substrate will be described.

First, as shown in (A) of FIG. 3, a silicon nitride film 20 is formed on a silicon carbide substrate 12.

The silicon nitride film 20 can be formed by any method such as a plasma CVD method, a LP (low pressure) CVD method, or an ALD method.

In the plasma CVD, for example, ammonia gas (NH₃) is decomposed into reactive ions by plasma energy and silane gas (SiH₄) is decomposed into reactive ions by thermal divergence or plasma energy. And then, the divergent reactive ions react on and over the silicon carbide substrate 12 and are deposited as a silicon nitride film (Si₃N₄).

Some reactive ions produce hydrogen (H₂), which is emitted from the reactor. To supply source gas or reactive ions and generate the flow to emit gases, hydrogen gas may be supplied simultaneously.

In LP (low pressure) CVD, for example, a silicon nitride film (Si₃N₄) is formed by a decomposition reaction and a synthetic reaction by a thermal reaction while further adding nitrogen gas (N₂) or hydrogen gas (H₂) to di-chloro-silane gas (SiH₂Cl₂) and ammonia gas (NH₃). Some are emitted from the reactor as hydrochloric acid (HCl) and hydrogen (H₂).

The silicon nitride film 20 may be a nitrogen-rich nitride film. In the step of forming the silicon nitride film 20, the ratio of nitrogen atom/silicon atom of supply gas can be made larger than 1 in order to form a nitrogen-rich nitride film.

When the silicon nitride film 20 is formed by CVD method, according to an example, nitrogen atoms are adsorbed on the surface of the silicon carbide substrate 12 by supplying only a gas containing nitrogen atoms first, and then, the silicon nitride film 20 is formed by supplying a gas containing silicon atoms.

When the silicon nitride film 20 is formed by CVD method, according to another example, nitrogen atoms and hydrogen atoms are adsorbed on the surface of the silicon carbide substrate 12 by supplying a hydrogen gas in addition to a gas containing nitrogen atoms first, and then, the silicon nitride film 20 is formed by supplying a gas containing silicon atoms.

When the silicon nitride film 20 is formed by the plasma CVD method, for example, a plasma-converted gas is supplied to the silicon carbide substrate 12 by supplying only a gas containing nitrogen atoms first.

Next, a gas containing silicon atoms is also supplied and the silicon nitride film 20 is formed by synthesis of reactive ions separated by plasma. Due to the presence of reactive ions containing excessive nitrogen atoms, the nitrogen atoms or (—NH₂) are bonded to the dangling bond on the outermost surface of the semiconductor substrate 10, or the nitrogen atoms are incorporated into interstitial sites of a silicon nitride crystal. As a result, the silicon nitride film 20 becomes nitrogen-rich.

According to another example, when the silicon nitride film 20 is formed by the plasma CVD method, both a gas containing nitrogen atoms and a hydrogen gas in a state of being converted into plasma are supplied to the front face of the silicon carbide substrate 12.

Next, the silicon nitride film 20 is formed by suppling the gas containing silicon atoms also.

When the silicon nitride film 20 is formed by LP (low pressure) CVD method, for example, the rate of the supply amount per unit time of the nitrogen atoms contained in the gas containing nitrogen atoms is increased to start the film formation with respect to the supply amount per unit time of the silicon atoms contained in the gas containing silicon atoms.

Then, the reactive groups containing excess nitrogen are bonded to the dangling bond of the surface or mixed between the lattices, etc. to make the silicon nitride film 20 nitrogen rich by advancing the film formation with the supply amount per unit time of the nitrogen atoms is decreased with respect to the supply amount per unit time of the silicon atoms.

Forming the nitrogen-rich nitride film in this way increases the nitrogen surface density of the surface of the silicon carbide substrate 12.

According to an example, in the step of forming the silicon nitride film 20, the temperature of the silicon carbide substrate 12 can be less than 900° C. For example, the substrate temperature can be reduced to about 300° C. to 400° C. in the case of the plasma CVD method.

According to another example, when the silicon nitride film 20 is formed by CVD LP (low pressure), the flow rate of the di-chloro-silane gas (SiH₂Cl₂) and ammonia gas (NH₃) is fixed and the temperature of the silicon carbide substrate is 700° C. to 760° C., then the silicon nitride film 20 was formed.

Here, the flow rate between the di-chloro-silane gas and the ammonia gas can be fixed at 10.

A particularly nitrogen-rich film can be formed by setting the temperature of the silicon carbide substrate 12 to about 700° C. to 760° C.

When the temperature of the silicon carbide substrate 12 was set to 700° C., the silicon nitride film 20 having a composition ratio of the nitrogen element to the silicon element (N/Si) of about 1.34 to 1.39 was formed.

Further, when the temperature of the silicon carbide substrate 12 was set to 750° C., the silicon nitride film 20 having a composition ratio of the nitrogen element to the silicon element (N/Si) of about 1.37 to 1.45 has been formed.

When the temperature of the silicon carbide substrate was set to 780° C., the silicon nitride film 20 having a composition ratio of the nitrogen element to the silicon element (N/Si) of about 1.18 to 1.22 was formed.

The first nitride film 14 having a composition ratio of the nitrogen element to the silicon element (N/Si) of 1.34 or more and 1.45 or less can be provided by the process of setting the temperature to 700° C. to 760° C.

Further, when the oxidation rate of the silicon nitride film formed at 725° C. to 750° C. and the silicon nitride film formed at 650° C. was investigated, the silicon nitride film formed at 725° C. to 750° C. was observed to be slower.

The composition ratio of the nitrogen element to the silicon element (N/Si) of the silicon nitride film formed at 650° C. is about 1.28 to 1.35, and is smaller than the composition ratio of the nitrogen element of the silicon element (N/Si) of the silicon nitride film formed at 725° C. to 750° C. Oxidation is suppressed or easily controlled by depositing the silicon nitride film having a small composition ratio (N/Si) on the silicon nitride film having a large composition ratio (N/Si).

According to another example, under condition that the flow rate ratio of di-chloro-silane gas and ammonia is 1, the composition ratio of the nitrogen element to the silicon element (N/Si) is maximized when the temperature of the silicon carbide substrate is 600° C. The composition ratio of the nitrogen element to the silicon element (N/Si) varies depending on the flow rate ratio and the temperature.

In some examples described herein, it is preferable to adjust condition of both the flow rate ratio and the temperature of silicon carbide substrate by increasing the flow rate ratio of the di-chloro-silane gas and the ammonia in order to stack the first nitride layer and the second nitride layer having different compositional ratios (N/Si).

Before forming the silicon nitride film 20 on the surface of the silicon carbide substrate 12, the surface of the silicon carbide substrate 12 may be annealed with ammonia (NH₃).

As a result, oxygen atoms bonded by water molecules, oxygen molecules and (—OH) or the like on the upper surface of the silicon carbide substrate 12 can be removed or replaced with (—NO), (—NH₂), H, or N bonds. In these cases, if the temperature of the silicon carbide substrate is high, the surface can be nitrided.

Next, as shown in (B) of FIG. 3, a silicon film 22 is formed on the silicon nitride film 20.

The silicon film 22 can be formed by, for example, a sputtering method without substrate heating.

For example, ion beam sputtering or magnetron sputtering may be adopted.

In another embodiment, when the silicon film 22 is formed by CVD method, the silicon nitride film can be continuously formed in the same reactor by switching to supplying only SiH₄ or di-chloro-silane following the formation of the silicon nitride film.

Next, as shown in (C) of FIG. 3, the silicon film 22 is oxidized. As a result, the silicon oxide film 18 is formed. During this oxidation treatment, all or a part of the silicon nitride film 20 becomes silicon oxynitride.

In the example shown in (C) of FIG. 3, the silicon nitride film 20 becomes entirely silicon oxynitride, and the first nitride film 14 and the second nitride film 16 are provided.

In the example shown in (C′) of FIG. 3, a part of the silicon nitride film 20 becomes the second nitride film 16 that is a silicon oxynitride, and the remaining part of the silicon nitride film 20 becomes the first nitride film 14.

According to an example, in the step of forming the silicon film 22, the temperature of the silicon carbide substrate 12 can be set to be higher than the oxidation starting temperature of silicon and lower than the oxidation starting temperature of silicon carbide. Such a temperature range is, for example, 800° C. or more and less than 900° C.

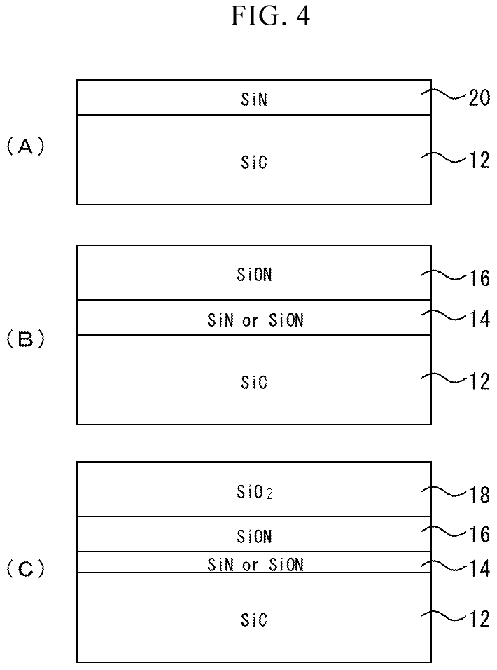

FIG. 4 shows a method of producing a semiconductor substrate according to another example. First, as shown in (A) of FIG. 4, the silicon nitride film 20 is formed on the silicon carbide substrate 12. Since the formation of the silicon nitride film 20 is as described above, the description thereof will be omitted.

Next, as shown in (B) of FIG. 4, at least a portion of the silicon nitride film 20 is oxidized to form silicon oxynitride. As a result of the oxidation treatment, the first nitride film 14 and the second nitride film 16 are provided.

When all of the silicon nitride film 20 is oxidized by this oxidation treatment, the first nitride film 14 and the second nitride film 16 become SiON.

On the other hand, when a part of the silicon nitride film 20 is oxidized by this oxidation treatment, the first nitride film 14 becomes SiN and the second nitride film 16 becomes SiON.

According to an example, oxidation of the silicon carbide substrate 12 can be suppressed on condition that the temperature of the silicon carbide substrate 12 in this step is set to be less than 900° C.

Next, as shown in (C) of FIG. 4, the silicon oxide film 18 is formed on the second nitride film 16 that is a silicon oxynitride. The silicon oxide film 18 can be formed by, for example, the plasma CVD method using nitric oxide (N₂O) or oxygen (O₂) and silane (SiH₄).

According to an example, the silicon oxide film 18 can be formed by the plasma CVD method with the silicon carbide substrate 12 having a temperature of 400° C. or higher and lower than 900° C.

In the process described with reference to FIGS. 3 and 4, the upper surface of the silicon carbide substrate 12 is not directly oxidized or an oxide film is not directly formed on the upper surface. Therefore, it is possible to provide a semiconductor substrate having a high channel mobility and a low interface state density and maintaining the good interface by keeping the bonding of N bonded to the interface between the upper film and the silicon carbide substrate 12 (—NH₂) or a part of (—NO) or the like.

While several aspects of at least one embodiment have been described, it is to be understood that various modifications and improvements will readily occur to those skilled in the art. Such modifications and improvements are intended to be part of the present disclosure and are intended to be within the scope of the present disclosure.

It is to be understood that the embodiments of the methods and apparatus described herein are not limited in application to the structural and ordering details of the components set forth in the foregoing description or illustrated in the accompanying drawings. Methods and apparatus may be implemented in other embodiments or implemented in various manners.

Specific implementations are given here for illustrative purposes only and are not intended to be limiting.

The phraseology and terminology used in the present disclosure are for the purpose of description and should not be regarded as limiting. The use of “including,” “comprising,” “having,” and variations thereof herein means the inclusion of the items listed hereinafter and equivalents thereof, as well as additional items.

The reference to “or” may be construed so that any term described using “or” may be indicative of one, more than one, and all of the terms of that description.

References to front, back, left, right, top, bottom, and side are intended for convenience of description. Such references are not intended to limit the components of the present disclosure to any one positional or spatial orientation. Accordingly, the foregoing description and drawings are by way of example only.

What is claimed is:

1. A semiconductor substrate comprising:
a silicon carbide substrate;
a first nitride film in contact with an upper surface of the silicon carbide substrate;
a second nitride film in contact with an upper surface of the first nitride film; and
a silicon oxide film in contact with an upper surface of the second nitride film,
wherein the first nitride layer is more nitrogen-rich than the second nitride layer.

2. The semiconductor substrate according to claim 1, wherein a thickness of the silicon oxide film is larger than a total thickness of the first nitride film and the second nitride film.

3. The semiconductor substrate according to claim 2, wherein the thickness of the silicon oxide film is 3 to 50 times the total thickness of the first nitride film and the second nitride film.

4. The semiconductor substrate according to claim 1, wherein the first nitride film and the second nitride film is a silicon oxynitride.

5. The semiconductor substrate according to claim 1, wherein a compound constituting the first nitride film is more nitrogen-rich than a stoichiometric composition of the first nitride film.

6. The semiconductor substrate according to claim 1, wherein a composition ratio of a nitrogen element to a silicon element is 1.34 or more and 1.45 or less in a compound forming of the first nitride film.

7. A method for producing a semiconductor substrate, the method comprising:
a step of forming a silicon nitride film on a silicon carbide substrate;
a step of forming a silicon film on the silicon nitride film; and
a step of oxidizing the silicon film.

8. The method for producing the semiconductor substrate according to claim 7, wherein in the step of forming the silicon nitride film, a nitrogen atom/silicon atom ratio contained in a supply gas is greater than 1.

9. The method for producing the semiconductor substrate according to claim 7, wherein in the step of forming the silicon nitride film, a temperature of the silicon carbide substrate is less than 900° C.

10. The method for producing the semiconductor substrate according to claim 7, wherein in the step of forming the silicon nitride film, a temperature of the silicon carbide substrate is set to 300° C. to 400° C.

11. The method for producing the semiconductor substrate according to claim 7, wherein in the step of forming the silicon nitride film, nitrogen atoms are adsorbed on a surface of the silicon carbide substrate by supplying only a gas containing nitrogen atoms first, and then, the silicon nitride film is formed by supplying a gas containing silicon atoms.

12. The method for producing the semiconductor substrate according to claim 7, wherein in the step of forming the silicon nitride film, nitrogen atoms and hydrogen atoms are adsorbed on a surface of the silicon carbide substrate by supplying a hydrogen gas in addition to a gas containing nitrogen atoms, and then, the silicon nitride film is formed by supplying a gas containing silicon atoms.

13. The method for producing the semiconductor substrate according to claim 7, wherein in the step of forming the silicon nitride film, a gas containing nitrogen atoms is in a state of being converted into plasma and supplied to a surface of the silicon carbide substrate, and then, the silicon nitride film is formed by supplying a gas containing silicon atoms.

14. The method for producing the semiconductor substrate according to claim 7, wherein in the step of forming the silicon nitride film, a hydrogen gas and a gas containing nitrogen atoms are both in a state of being converted into plasma and supplied to the surface of the silicon carbide substrate, and then, the silicon nitride film is formed by supplying a gas containing silicon atoms.

15. The method for producing the semiconductor substrate according to claim 7, wherein in the step of forming the silicon nitride film, a ratio of a supply amount per unit time of nitrogen atoms is increased to start a film formation with respect to a supply amount per unit time of silicon atoms contained in a gas containing silicon atoms, and then, the supply amount per unit time of the nitrogen atoms is lowered with respect to the supply amount per unit time of the silicon atoms to advance the film formation.

16. The method for producing the semiconductor substrate according to claim 7, wherein in the step of oxidizing the silicon film, a temperature of the silicon carbide substrate is set to be higher than an oxidation start temperature of silicon and lower than an oxidation start temperature of silicon carbide.

17. A method for producing a semiconductor substrate, the method comprising:
a step of forming a silicon nitride film on a silicon carbide substrate;
a step of oxidizing the silicon nitride film to a silicon oxynitride; and
a step of forming a silicon oxide film on the silicon oxynitride.
